(19) United States
(12) Patent Application Publication
(10) Pub. No.: US 2012/0169188 A1
(43) Pub. Date: Jul. 5, 2012

(54) DRIVE ENCLOSURE

(75) Inventors: CHEN-LU FAN, Tu-Cheng (TW); LI-PING CHEN, Tu-Cheng (TW)

(73) Assignee: HON HAI PRECISION INDUSTRY CO., LTD., Tu-Cheng (TW)

(21) Appl. No.: 13/241,972

(22) Filed: Sep. 23, 2011

(30) Foreign Application Priority Data
Dec. 30, 2010 (TW) 099146845

(51) Int. Cl. H05K 5/02

(52) U.S. Cl. 312/223.1

(57) ABSTRACT

A drive enclosure includes a chassis and a separating assembly. The chassis includes a bottom plate, a side plate, and a middle plate attached to the side plate and substantially parallel to the bottom plate. A securing portion is located on the bottom plate. A first positioning portion and a second positioning portion are located on the middle plate. The first positioning portion and the securing portion have a same configuration and the first positioning portion is aligned with the securing portion, and the second positioning portion is adjacent to the first positioning portion. The separating assembly includes a first securing piece and a second securing piece. The first securing piece is engaged with the securing portion and the first positioning portion, and the second securing piece is engaged with the second positioning portion.

### BACKGROUND

1. Technical Field

The present disclosure relates to electronic device enclosures, and more particularly to a drive enclosure.

2. Description of Related Art

An enclosure, such as a drive enclosure, has a housing which can receive hard disk drives. The housing includes a bottom wall, two sidewalls, and a top wall. A plurality of separating plates and a plurality of mounting plates are located between the top wall and the bottom wall, to divide the housing to a plurality of receiving spaces. Each mounting plate is attached to each separating plate. Screws are typically used to secure the mounting plate to the separating plate, but are time-consuming and inconvenient.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a partially exploded, cutaway view of a drive enclosure in accordance with an embodiment.

FIG. 2 is an isometric view of a separating plate in accordance with an embodiment.

FIG. 3 is similar to FIG. 1, and two separating plates of the drive enclosure are secured to a bracket.

FIG. 4 is an assembled view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

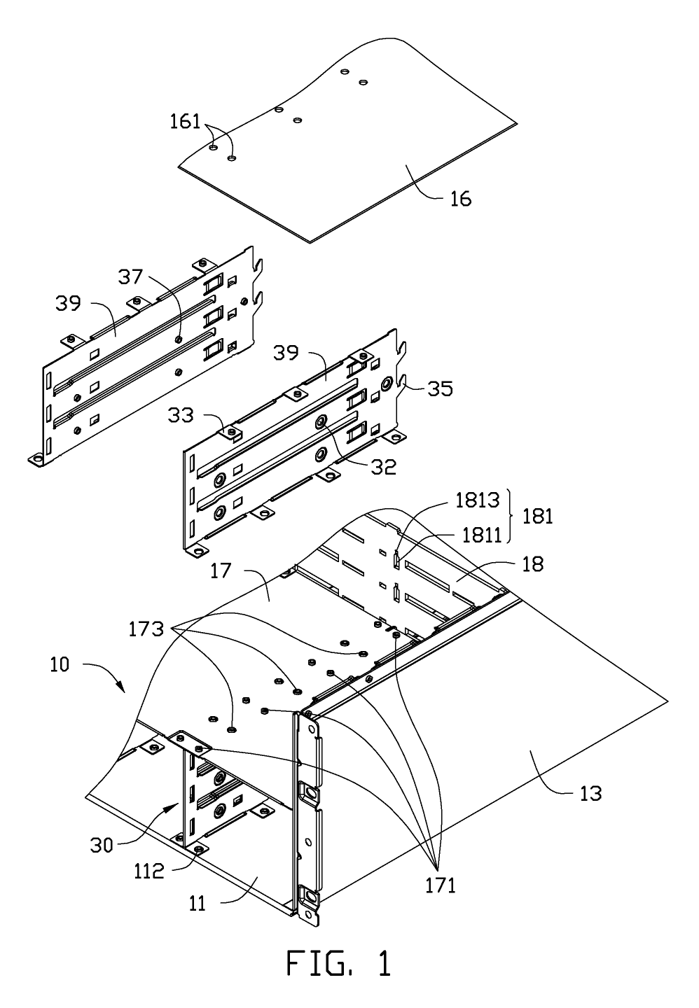

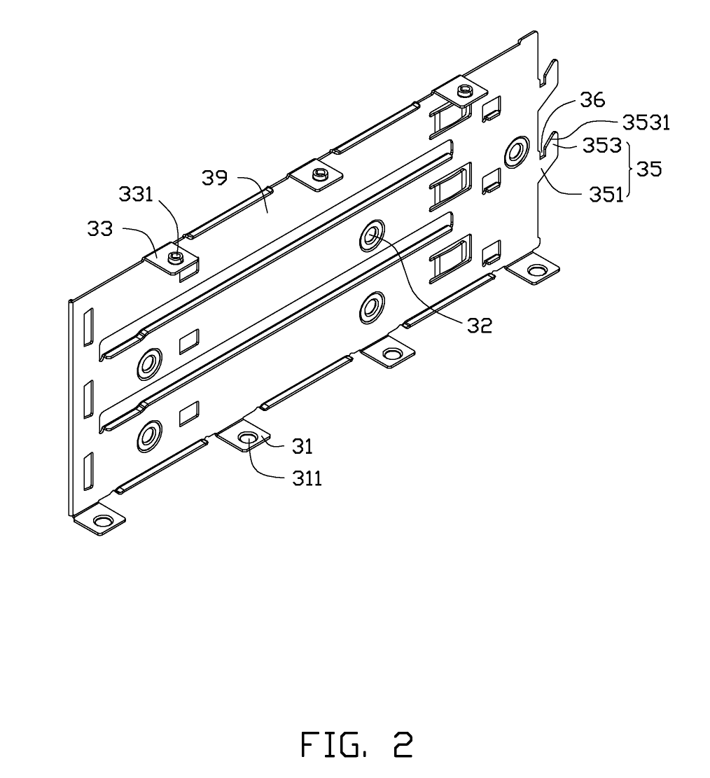

Referring to FIGS. 1 and 2, a drive enclosure in accordance with an embodiment includes a bracket 10 and a plurality of separating assemblies 30 received in the bracket 10. In one embodiment, the bracket 10 can receive a plurality of hard disk drives.

The bracket 10 includes a bottom plate 11, two side plates 13 (only one shown in FIG. 1) connected to opposite sides of the bottom plate 11, a top plate 16 covering the bracket 10, and a middle plate 17 connected to the two side plates 13. In one embodiment, the top plate 16 is substantially parallel to the middle plate 17 and the bottom plate 11, and the side plate 13 is substantially perpendicular to the bottom plate 11.

A plurality of securing portions 112 (two shown in FIG. 1) protrudes from the bottom plate 12. In one embodiment, each securing portion 112 may be a securing post or a securing pin. Every four of the plurality of securing portions 112 are arranged in a first line substantially parallel to the side plate 13. Every two of the plurality of securing portions 112 are adjacent to each other and arranged in a second line substantially perpendicular to the side plate 13. A plurality of receiving holes 161 are defined in the top plate 16. In one embodiment, every six of the plurality of receiving holes 161 are arranged together.

The middle plate 17 includes a plurality of first positioning portions 171 and a plurality of second positioning portions 173. In one embodiment, each first positioning portion 171 has a configuration corresponding to the securing portion 112. Each second positioning portion 173 may be a positioning hole or a positioning slot. Every four of plurality of first positioning portions 171 and every three of the plurality of second positioning portions 173 are arranged in the first line, and every second positioning portion 173 is located between every two adjacent first positioning portion 171.

A retaining plate 18 mounted on the rear of the bottom plate 11, defines a plurality of sliding slots 181. In one embodiment, every four of the plurality of sliding slots 181 are towards to the plurality of first and second positioning portion 171, 173 and securing portions 112. The four sliding slots 181 are arranged in a third line substantially perpendicular to the bottom plate 11. Each sliding slot 181 includes a guiding portion 1811 and a retaining portion 1813 communicating with the guiding portion 1811. In one embodiment, a width of the guiding portion 1811 is larger than that of the retaining portion 1813.

Each separating assembly 30 includes two separating plates 39 arranged back to back. Four first securing pieces 31, each with a securing hole 311, extend from a first edge of each separating plate 39. Three second securing pieces 33, each with a securing post 331, extend from a second opposite edge of the separating plate 39. Two clamps 35 extend from a third edge of the separating plate 39. Each clamp 35 includes a connecting portion 351 and an extending portion 353 substantially perpendicular to the connecting portion 351. In one embodiment, the connecting portion 351 is located at the same plane to the separating plate 39. A cutout 36 is defined between the separating plate 39 and the extending portion 353. In one embodiment, a slant edge 3531 is defined in the extending portion 353 and towards to the cutout 36. A width of the cutout 36 is larger than the thickness of the retaining piece 18, and the thickness of the clamp 35 is less than the width of the retaining portion 1813. In one embodiment, each separating plate 39 is a metal plate.

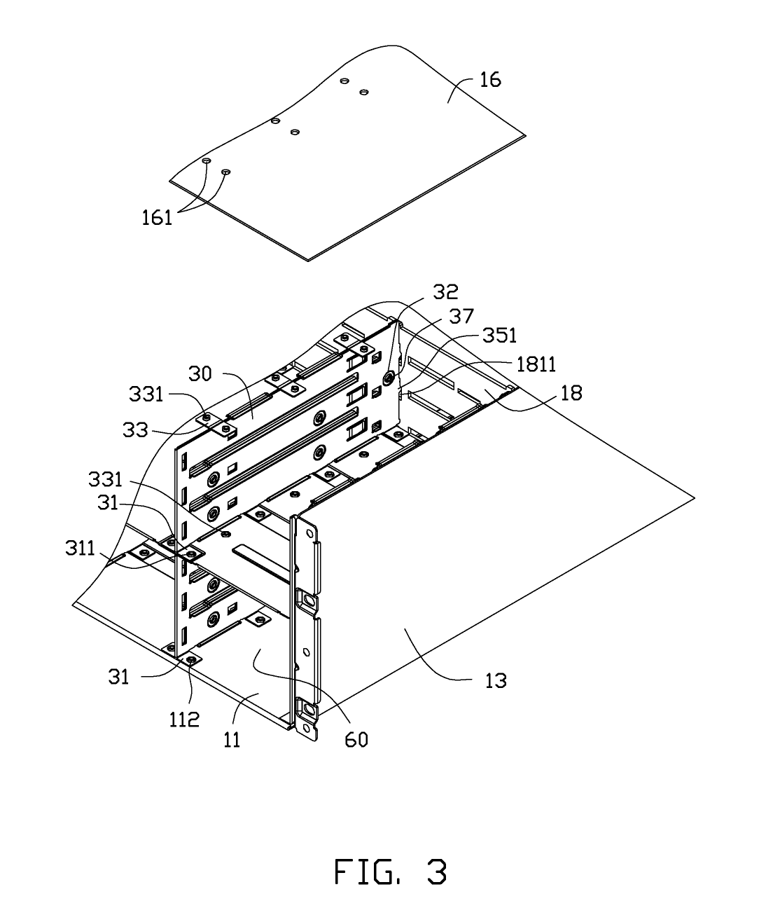

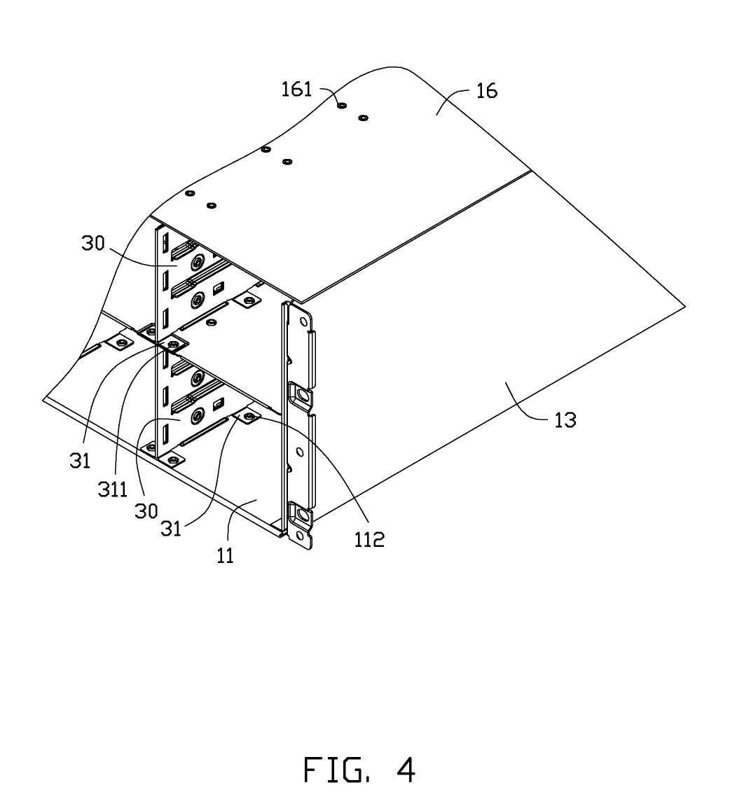

Referring to FIGS. 3-4, in assembly, the retaining plate 18 is detached from the bottom plate 11. A plurality of first separating assemblies 30, each with two separating plates 39 abutting back to back, is located between the bottom plate 11 and the middle plate 17. The securing portions 112 are received in the corresponding securing holes 311, and the securing posts 331 are received in the corresponding second positioning portions 173. A plurality of second separating assemblies 30, each with two separating plates 39 abutting back to back, is located between the middle plate 17 and the top plate 16. The first positioning portions 171 are received in the corresponding the securing holes 311, and the securing posts 331 is received in the corresponding receiving holes 16. In one embodiment, every two of each separating assembly 30 can be secured together by means, such as screws, jointing. For example, four mounting holes 32 are defined in one of the two separating plates 39, and four mounting posts 37 protrude from the other one of the two separating plates 39. Therefore, the four mounting posts 37 are engaged in the four mounting holes 32, to secure the two separating plates 39 together.

The retaining plate 18 is placed on the bottom plate 11 and located between the two side plates 13. Each clamp 35 is received in the guiding portion 1811. The retaining plate 18 is pushed downward substantially perpendicular to the bottom plate 11, to slide the clamp 35 to the retaining portion 1813. Therefore, an edge of each retaining portion 1813 can be engaged in each retaining slot 36, so that the retaining plate 18 is secured to the plurality of separating plates 39. The middle plate 17 and the plurality of separating assemblies 30 together divide the bracket 10 to a plurality of receiving houses to house a plurality of drives.

In disassembly, the retaining plate 18 is moved upward, to slide the connecting portions 351 in the guiding portions 1811. The clamps 35 are removed from the guiding portions 1811, to detach the retaining plate 18 from the bracket. The securing posts 331 are clearance through the second positioning portions 173 and the receiving holes 161. The securing holes 311 are disengaged from the securing portions 112 and the first positioning portions 171. Therefore, each separating assembly 30 can be removed from the bracket 10.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A drive enclosure comprising:
a chassis comprising a bottom plate, a side plate, and a middle plate attached to the side plate and substantially parallel to the bottom plate;
a securing portion located on the bottom plate;
a first positioning portion and a second positioning portion located on the middle plate, the first positioning portion and the securing portion having a same configuration, the first positioning portion being aligned with the securing portion, and the second positioning portion being adjacent to the first positioning portion; and
a separating assembly comprising a first securing piece and a second securing piece;
wherein the first securing piece is adapted to engage with the securing portion or the first positioning portion, and the second securing piece is adapted to engage with the second positioning portion.

2. The drive enclosure of claim 1, wherein the first positioning portion and the securing portion are located in a line substantially perpendicular to the bottom plate.

3. The disk drive enclosure of claim 1, further comprising a retaining plate, wherein the separating assembly comprises a clamp engaged with the retaining plate.

4. The drive enclosure of claim 3, wherein a sliding slot is defined in the retaining plate, and comprises a guiding portion and a retaining portion communicating with the guiding portion, and the clamp is slid in the guiding portion and engaged in the retaining portion.

5. The drive enclosure of claim 4, wherein an extending direction of the sliding slot is substantially perpendicular to the bottom plate.

6. The drive enclosure of claim 4, wherein the clamp comprises a connecting portion and an extending portion connected to the connecting portion, a cutout is defined in the separating assembly and adjacent to the extending portion, and an edge of the retaining portion is received in the cutout.

7. The drive enclosure of claim 6, wherein the extending portion is substantially perpendicular to the connecting portion.

8. The drive enclosure of claim 1, wherein the securing portion is a post, and a securing hole is defined in the first securing piece to receive the securing portion.

9. The drive enclosure of claim 1, wherein the second positioning portion is a receiving hole, and a securing post is located on the second securing piece and engaged in the receiving hole.

10. The drive enclosure of claim 1, wherein the separating assembly further comprises two separating plates attached to back to back.

11. A drive enclosure comprising:
a chassis comprising a bottom plate, a side plate, a top plate covering on the side plate, and a middle plate attached to the side plate located between the top plate and the bottom plate and substantially parallel to the bottom plate;
at lease one separating assembly comprising a first securing piece and a second securing piece;
wherein the at least one separating assembly is located at a first position or a second position; if the at least one separating assembly is located in the first position, the at least one separating assembly is located between the bottom plate and the middle plate, the first securing piece is attached to the bottom plate, and the second securing piece is attached to the middle plate; if the at least one separating assembly is located in the second position, the at least one separating assembly is located between the middle plate and the top plate, the first securing piece is attached to the middle plate, and the second securing piece is attached to the top plate.

12. The drive enclosure of claim 11, further comprising a securing portion engaged with the first securing piece and located on the bottom plate, and a first positioning portion having a same configuration as the securing portion and engaged with the first securing piece on the middle plate, and the securing portion is aligned with the first positioning portion.

13. The drive enclosure of claim 11, wherein the first positioning portion and the securing portion are located in a line substantially perpendicular to the bottom plate.

14. The drive enclosure of claim 12, wherein the securing portion is a post, and a securing hole is defined in the first securing piece to receive the securing portion.

15. The drive enclosure of claim 12, wherein a second positioning portion engaged with the second securing piece, is located on the middle plate, and the second positioning portion is adjacent to the first positioning portion.

16. The drive enclosure of claim 15, wherein the second positioning portion is a receiving hole, and the second securing piece comprises a securing post engaged in the receiving hole.

17. The drive enclosure of claim 11, further comprising a retaining plate, wherein the separating assembly comprises a clamp engaged with the retaining plate.

18. The drive enclosure of claim 17, wherein a sliding slot is defined in the retaining plate, and comprises a guiding portion and a retaining portion communicating with the guiding portion, and the clamp is slid in the guiding portion and engaged in the retaining portion.

19. The drive enclosure of claim 18, wherein the clamp comprises a connecting portion and an extending portion connected to the connecting portion, a cutout is defined in the separating assembly and adjacent to the extending portion, and an edge of the retaining portion is received in the cutout.

20. The drive enclosure of claim 11, wherein the separating assembly comprises two separating plates attached back to back.
